(19) United States
(12) Patent Application Publication
(10) Pub. No.: US 2005/0218472 A1
(43) Pub. Date: Oct. 6, 2005

(54) Semiconductor device manufacturing method thereof

(75) Inventors: Tetsuya Okada, Kumagaya-city (JP); Akihiko Funakoshi, Kyoto-city (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd, Moriguchi-city (JP)

(21) Appl. No.: 11/090,298

(22) Filed: Mar. 28, 2005

(30) Foreign Application Priority Data
Mar. 29, 2004 (JP) 2004-094689

(51) Int. Cl. H01L 27/095; H01L 21/338

(52) U.S. Cl. 257/471; 438/92; 438/167

(57) ABSTRACT

A trench is provided, which penetrates a channel layer between adjacent gate electrodes in a MOSFET, and a Schottky metal layer is provided in the trench. Accordingly, a bottom of the trench becomes a Schottky barrier diode. Thus, the Schottky barrier diode can be included in a diffusion region of the MOSFET. Consequently, miniaturization of the device and reduction in the number of components can be realized.

### BACKGROUND OF THE INVENTION

1. Field of the Invention

The present invention relates to a semiconductor device and a manufacturing method thereof, and more particularly relates to a semiconductor device in which a Schottky barrier diode is included in a MOSFET, and a manufacturing method thereof.

2. Description of the Related Art

FIG. 14 shows a structure of a conventional MOSFET by taking an n-channel MOSFET as an example.

The MOSFET 200 includes a semiconductor substrate 130, a channel layer 133, a source region 134, a gate oxide film 135, and a gate electrode 136.

The semiconductor substrate 130 is obtained by laminating an n− type epitaxial layer 132 on an n+ type silicon semiconductor substrate 131. The n− type epitaxial layer 132 becomes a drain region.

The channel layer 133 is an impurity diffusion region provided by implanting p+type ions by a dose of 1.0×10¹³ to 1.0×10¹⁴ cm⁻² into a surface of the semiconductor substrate in a field portion.

The source region 134 is an n+ type impurity diffusion region provided by ion implantation of phosphorous or arsenic into a surface of the channel layer 133. The source region 134 comes into contact with a source electrode 139 provided by sputtering aluminum or its alloy on the entire surface.

Moreover, a body region 140 is provided in order to suppress an operation of a parasitic bipolar transistor and improve strength against avalanche breakdown.

The gate oxide film 135 is a thermal oxide film provided on the surface of the semiconductor substrate and has a thickness of several hundred angstroms according to a drive voltage.

The gate electrode 136 is provided on the gate oxide film 135 between the adjacent source regions 134 in the surfaces of the channel layer 133. A resistance is lowered by introducing impurities into polysilicon. Thus, the gate electrode 136 is obtained. The gate electrode 136 is insulated from the source electrode 139, by use of an oxide film 137 or the like which covers a periphery of the gate electrode. This technology is described for instance in Japanese Patent Application Publication No. 2000-40818.

FIG. 15A shows a circuit diagram of the MOSFET described above.

The MOSFET 200 has a parasitic pn junction diode Dₚₙ between a source and a drain. FIG. 15A schematically shows the parasitic diode of the MOSFET.

Generally, when a load of a bridge circuit is an L component, the parasitic pn junction diode Dₚₙ is used as a fast recovery diode (FRD). For example, this diode is used in a motor drive application and the like.

However, a forward rise voltage VF of the parasitic pn junction diode Dₚₙ is as high as about 0.6 V, which becomes a factor that hinders a high-speed switching operation and low power consumption. Moreover, in the case of the pn junction diode, when a forward voltage is applied (on state), carriers (holes) are implanted into an n type region from a p type region. Meanwhile, when a reverse voltage is applied, first, the carriers accumulated in the n type region flow out or are recombined. Thereafter, a depletion layer starts to spread. Specifically, before an off state is set, time (reverse recovery time: Trr) for flow-out or recombination of the carriers is produced. This time also becomes the factor that hinders the high-speed operation.

Specifically, in the case where the high-speed switching operation is not required so much, such as in the motor drive application, the parasitic pn junction diode Dₚₙ can be used as the FRD. However, in the case where the high-speed operation is required, the parasitic pn junction diode is not suitable.

Consequently, an external Schottky barrier diode is often used. FIG. 15B shows a circuit diagram thereof.

Accordingly, between the source and the drain of the MOSFET 200, the parasitic pn junction diode Dₚₙ and the external Schottky barrier diode D_{sbd} are connected in parallel.

The forward rise voltage VF of the pn junction diode is about 0.6 V, and a forward rise voltage VF of the Schottky barrier diode is about 0.4 V. Specifically, even if the both diodes are connected in parallel as shown in FIG. 15B, the Schottky barrier diode D_{sbd} will be operated first.

In other words, by providing the external Schottky barrier diode D_{sbd}, the forward voltage of the MOSFET 200 can be reduced. Furthermore, since no carriers are accumulated, there is an advantage that the reverse recovery time Trr can be reduced.

However, if the external Schottky barrier diode D_{sbd} is used, the number of components is increased, and cost reduction and miniaturization are limited.

Moreover, the MOSFET 200 is used by short-circuiting the source region 134 and the body region 140. However, the body region 140 has a high resistance, and, in reality, a potential difference is caused by the resistance between the source and the body. When this potential difference becomes 0.6 V or more, a parasitic bipolar operation is caused between the source, the, body and the drain. Thus, there arises a problem that a current value is drastically increased to cause breakdown.

### SUMMARY OF THE INVENTION

The present invention was made in consideration for the foregoing problems. First, a semiconductor device of the present invention includes: a one conductivity type semiconductor substrate; an opposite conductivity type channel layer provided in a surface of the substrate; a gate electrode which comes into contact with the one conductivity type semiconductor substrate through an insulating film; one conductivity type source regions which are provided in the surface of the substrate and adjacent to the gate electrode with the insulating film interposed therebetween; a trench provided in the semiconductor substrate between the source regions so as to penetrate the channel layer; a first metal layer which forms a Schottky junction with the one conductivity type semiconductor substrate exposed to the trench at least below the channel layer; and a second metal layer connected to the first metal layer, the channel layer and the source regions.

Second, a semiconductor device of the present invention includes: a one conductivity type semiconductor substrate; an opposite conductivity type channel layer provided in a surface of the substrate; a plurality of first trenches which are provided in the substrate and penetrate the channel layer; second trenches which are disposed alternately with the first trenches in the substrate and penetrate the channel layer; gate electrodes buried in the first trenches with an insulating film interposed therebetween; one conductivity type source regions which are adjacent to the gate electrodes with the insulating film interposed therebetween at the surface of the substrate; a first metal layer which forms a Schottky junction with the one conductivity type semiconductor substrate exposed to the second trenches at least below the channel layer; and a second metal layer connected to the first metal layer, the channel layer and the source regions.

Moreover, the first metal layer is provided so as to partially come into contact with the source regions and the channel layer, and the second metal layer is connected to the source regions and the channel layer through the first metal layer.

Third, a method for manufacturing a semiconductor device of the present invention includes the steps of: forming a gate electrode which comes into contact with a surface of a one conductivity type semiconductor substrate through an insulating film; forming an opposite conductivity type channel layer in the one conductivity type semiconductor substrate, and forming a one conductivity type impurity region in a surface of the channel layer; forming a trench penetrating the channel layer in the semiconductor substrate between the gate electrodes, and forming source regions; forming a first metal layer which forms a Schottky junction with the one conductivity type semiconductor substrate exposed to the trench at least below the channel layer; and forming a second metal layer connected to the first metal layer, the channel layer and the source regions.

Fourth, a method for manufacturing a semiconductor device of the present invention includes the steps of: forming an opposite conductivity type channel layer in a surface of a one conductivity type semiconductor substrate; forming a plurality of first trenches penetrating the channel layer in the one conductivity type semiconductor substrate; forming an insulating film in the first trenches and forming gate electrodes; forming a one conductivity type impurity region in a surface of the channel layer; forming second trenches disposed alternately with the first trenches, and forming source regions; forming a first metal layer which forms a Schottky junction with the one conductivity type semiconductor substrate exposed to the second trenches at least below the channel layer; and forming a second metal layer connected to the first metal layer, the channel layer and the source regions.

Moreover, the source regions are formed by dividing the one conductivity type impurity region by use of the trench.

Moreover, the first metal layer is formed on the entire surface, and the second metal layer is formed on the entire surface.

According to embodiments of the present invention, a Schottky barrier diode can be included in a diffusion region of a MOSFET. If the Schottky barrier diode is used, no carriers are implanted in a rise operation. Thus, the carriers no longer flow out or are recombined when a turn off operation is started. Consequently, the reverse recovery time Trr can be reduced.

Moreover, compared to the pn junction diode, the forward rise voltage can also be reduced. Thus, a high efficiency semiconductor device for FRD or the like can be provided.

Furthermore, the Schottky barrier diode, which has been externally provided in the conventional case, can be included in the MOSFET. Thus, cost reduction and miniaturization of the device can be realized by reduction in the number of components.

Moreover, a body resistance is lowered by providing the first metal layer and/or the second metal layer in a depth direction of the channel along the sidewalls of the trench. Therefore, even if no body region is provided, an operation of a parasitic bipolar transistor is suppressed, and strength against avalanche breakdown can be improved.

### BRIEF DESCRIPTION OF THE DRAWINGS

FIG. 1 is a cross sectional view for explaining a semiconductor device of a first embodiment of the invention.

FIG. 2 is a cross sectional view for explaining a method for manufacturing a semiconductor device of the first embodiment of the invention.

FIG. 3 is a cross sectional view for explaining the method for manufacturing a semiconductor device of the first embodiment of the invention.

FIGS. 4A and 4B are cross sectional views for explaining the method for manufacturing a semiconductor device of the first embodiment of the invention.

FIG. 5 is a cross sectional view for explaining the method for manufacturing a semiconductor device of the first embodiment of the invention.

FIGS. 6A to 6C are cross sectional views for explaining a method for manufacturing a semiconductor device of a second embodiment of the invention.

FIG. 7 is a cross sectional view for explaining a semiconductor device of a third embodiment of the invention.

FIG. 8 is a cross sectional view for explaining a method for manufacturing a semiconductor device of the third embodiment of the invention.

FIG. 9 is a cross sectional view for explaining the method for manufacturing a semiconductor device of the third embodiment of the invention.

FIG. 10 is a cross sectional view for explaining the method for manufacturing a semiconductor device of the third embodiment of the invention.

FIGS. 11A and 11B are cross sectional views for explaining the method for manufacturing a semiconductor device of the third embodiment of the invention.

FIG. 12 is a cross sectional view for explaining the method for manufacturing a semiconductor device of the third embodiment of the invention.

FIG. 13 is a cross sectional view for explaining the method for manufacturing a semiconductor device of the third embodiment of the invention.

FIG. 14 is a cross sectional view for explaining a conventional semiconductor device.

FIGS. 15A and 15B are circuit diagrams for explaining the conventional semiconductor device.

### DESCRIPTION OF THE EMBODIMENTS

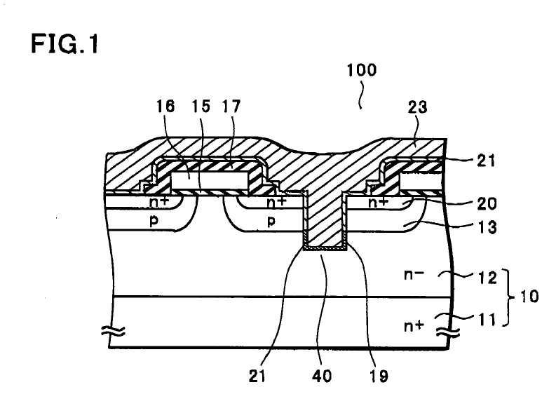

With reference to FIGS. 1 to 13, embodiments of the present invention will be described in detail by taking an n type channel MOSFET as an example.

First, with reference to FIGS. 1 to 5, a first embodiment will be described. FIG. 1 is a cross-sectional view showing a structure of a MOSFET.

The MOSFET 100 includes a one conductivity type semiconductor substrate 10, a channel layer 13, an insulating film 15, a gate electrode 16, a source region 20, a trench 19, a first metal layer 21, and a second metal layer 23.

The one conductivity type semiconductor substrate 10 is formed by laminating an n− type semiconductor layer 12 on an n+ type silicon semiconductor substrate 11 by use of an epitaxial growth method or the like. The n− type semiconductor layer 12 will be a drain region.

The channel layer 13 is a p+type impurity diffusion region provided in a surface of the n− type semiconductor layer 12. In a surface of the channel layer 13, the source region 20 is provided, which is obtained by diffusing phosphorus or arsenic after ion implantation thereof.

On a surface of the substrate 10 between the adjacent source regions 20, the gate oxide film 15 is provided, which is made of a thermal oxide film having a film thickness of several hundred angstroms according to a drive voltage. On the gate oxide film 15, the gate electrode 16 is provided. The gate electrode 16 is obtained by patterning a semiconductor layer such as polysilicon containing impurities or a conductor layer into a predetermined shape. The gate electrode 16 comes into contact with the surface of the substrate 10 through the gate insulating film 15. Accordingly, a MOS structure is formed. In the surface of the substrate 10, the source regions 20 are disposed at positions adjacent to the gate electrode 16 through the gate insulating film 15.

A periphery (sides and an upper surface) of the gate electrode 16 is covered with an interlayer insulating film 17 such as a PSG (phospho silicate glass) film.

The trench 19 is provided in the semiconductor substrate between the source regions 20. The trench 19 penetrates the channel layer 13 and reaches the n− type semiconductor layer 12. On sidewalls of the trench 19, ends of the source regions 20 and the channel layer 13 are exposed. On a bottom of the trench 19 below the channel layer 13, the n− type semiconductor layer 12 is exposed. The trench 19 has an opening of about 0.2 μm to 5 μm and a depth of about 1 μm to 10 μm according to the withstand voltage series.

The first metal layer 21 is a Schottky metal layer such as Mo, for example, which covers an inner wall of the trench 19 to form a Schottky junction with the n− type semiconductor layer 12 exposed to the trench 19 below the channel layer 13. Thus, a Schottky barrier diode 40 is provided in the bottom of the trench 19 by the n− type semiconductor layer 12 and the first metal layer 21 which is below the channel layer 13. The Schottky metal layer 21 may be Ti, W, Ni, Al or the like other than Mo.

In FIG. 1, the first metal layer 21 is provided over the entire surface. However, without being limited thereto, the first metal layer 21 may be provided so as to at least form the Schottky junction with the n− type semiconductor layer 12 exposed to the trench 19 below the channel layer 13, that is, at least on the inner wall of the trench 19 in the fine pattern hatched portion. Moreover, the trench 19 may be filled with the Schottky metal layer 21.

The second metal layer 23 is a metal electrode layer such as Al which forms a source electrode. The second metal layer 23 is provided on the entire surface and connected to the channel layer 13 and the source regions 20 through the Schottky metal layer 21. Moreover, the metal electrode layer 23 will be an anode electrode of the Schottky barrier diode 40.

Note that, if the Schottky metal layer 21 is provided only in the bottom of the trench 19 as described above, the source regions 20 and the channel layer 13 are connected directly to the metal electrode layer 23. Moreover, if the trench 19 is filled with the Schottky metal layer 21, the metal electrode layer 23 is provided on the surface of the substrate 10 and comes into contact with the Schottky metal layer 21.

Thus, a structure in which the Schottky barrier diode 40 is included in the MOSFET 100 is obtained. The MOSFET 100 also includes a parasitic pn junction diode between source and drain. However, since the Schottky barrier diode 40 has a lower forward rise voltage, the Schottky barrier diode is operated when the MOSFET 100 is operated. In this regard, this embodiment is similar to the above-described case with the external Schottky barrier diode (see FIG. 15B).

However, in this embodiment, since the Schottky barrier diode can be included in the diffusion region of the MOSFET, cost reduction and miniaturization can be realized by reduction in the number of components. Moreover, provision of the Schottky barrier diode suppresses a loss caused by an increase in reverse recovery time Trr and enables high efficiency and high frequency.

Furthermore, by providing the Schottky metal layer 21 and/or the metal electrode layer 23 in a depth direction of the channel layer 13 (in a direction perpendicular to the substrate 10) along the sidewalls of the trench 19, a body resistance is lowered. Thus, even if no body region is provided, an operation of a parasitic bipolar transistor is suppressed, and strength against avalanche breakdown can be improved.

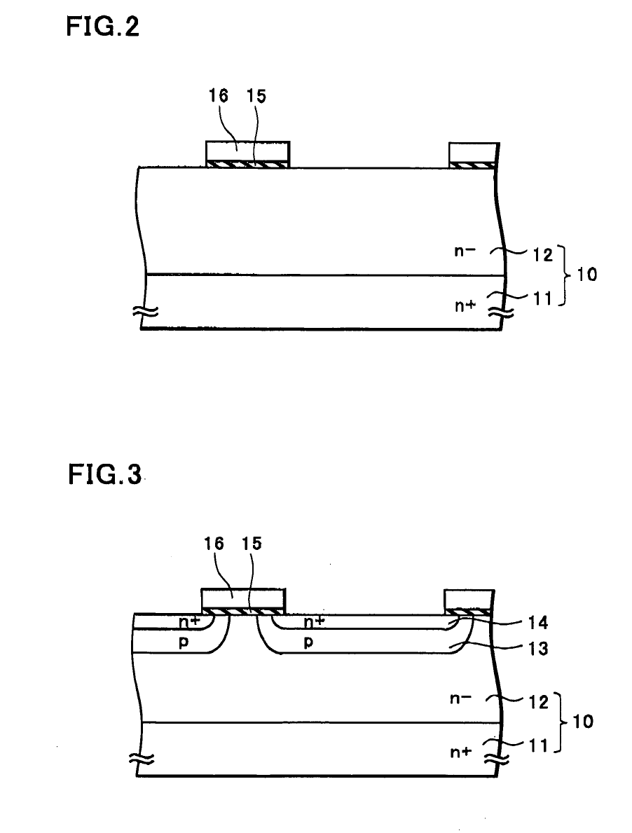

Next, with reference to FIGS. 2 to 5, a method for manufacturing the MOSFET of FIG. 1 will be described by taking the n type channel MOSFET as an example.

First step (FIG. 2): a step of forming a gate electrode which comes into contact with a surface of a one conductivity type semiconductor substrate through an insulating film.

First, an n type semiconductor substrate 10 is prepared, in which an n− type semiconductor layer 12 is laminated on an n+ type silicon semiconductor substrate 11 by use of the epitaxial growth method or the like. The n− type semiconductor layer 12 will be a drain region of the MOSFET.

The surface of the substrate 10 is oxidized at about 800° C., and a gate oxide film 15 is formed, which has a thickness of about several hundred angstroms according to the drive voltage.

Polysilicon, for example, is deposited on the entire surface of the gate oxide film 15 to form a semiconductor layer (or a conductor layer) 16. In order to lower a resistance, impurities are introduced into the semiconductor layer 16. Thereafter, the semiconductor layer 16 and the gate oxide film 15 are patterned into a predetermined shape, and the gate electrode 16 made of the semiconductor layer is formed.

Moreover, the semiconductor layer 16 may be one obtained by converting amorphous silicon into a single crystal by use of SPE (solid-phase epitaxy) or may be a single crystal silicon layer formed by depositing silicon molecules by use of MBE (molecular beam epitaxy).

Second step (FIG. 3): a step of forming an opposite conductivity type channel layer in the one conductivity type semiconductor substrate, and forming a one conductivity type impurity region in a surface of the channel layer.

By use of the gate electrode 16 as a mask, p type ions are implanted into the surface of the n− type semiconductor layer 12, for example, by a dose of 1.0×10¹³ to 1.0×10¹⁴ cm⁻². Thereafter, the ions are diffused to form a channel layer 13.

Moreover, n type impurities such as phosphorous and arsenic, for example, are implanted into the surface of the channel layer 13 and diffused therein to form an n+ type impurity region 14. Specifically, the n+ type impurity region 14 is provided in the surface of the channel layer 13 between two of the gate electrodes 15.

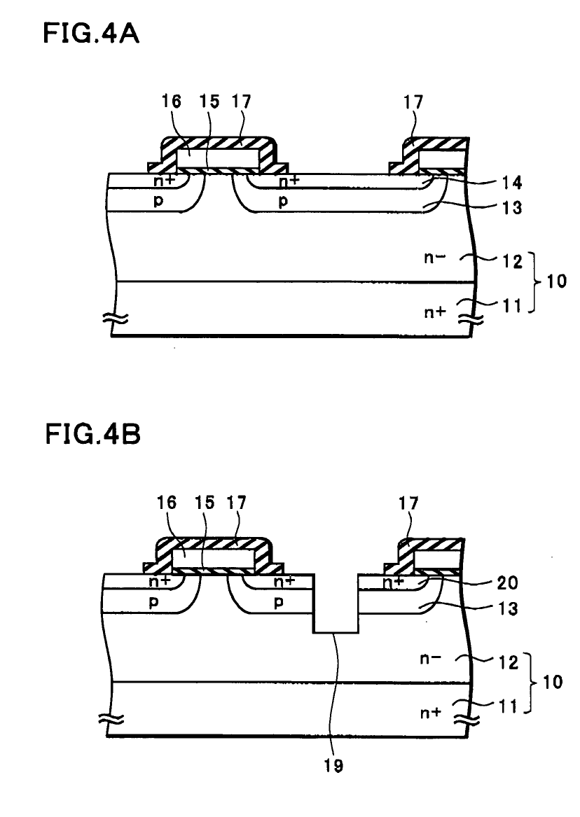

Third step (FIGS. 4A and 4B): a step of forming a trench penetrating the channel layer in the semiconductor substrate between the gate electrodes, and forming source regions.

An insulating film 17 such as a PSG film is formed on the entire surface and patterned, and the sides and the upper surface of the gate electrode 16 are covered with the interlayer insulating film 17. The interlayer insulating film 17 is patterned so as to be partially extended onto a surface of the n+ type impurity region 14. By performing the patterning as described above, a margin for misalignment of the mask can be secured, and etching of the gate oxide film 15 can be prevented (FIG. 4A).

Thereafter, a mask made of resist is provided so as to expose the surface of the substrate 10 between the gate electrodes 16, and the substrate 10 is subjected to anisotropic etching. Accordingly, a trench 19 is formed, which penetrates the channel layer 13 and reaches the n− type semiconductor layer 12. For example, the trench 19 has an opening of about 0.2 μm to 5 μm and a depth of about 1 μm to 10 μm according to the withstand voltage series.

Moreover, in this event, the n+ type impurity region 14 is simultaneously divided by the trench 19 to form a source regions 20. On the inner wall of the trench 19, the source regions 20 and the channel layer 13 are partially exposed. Moreover, in the bottom of the trench 19 below the channel layer 13, the n− type semiconductor layer 12 is exposed.

In such a manner, the resist mask is provided and the trench 19 is provided in the n− type semiconductor layer 12 inside the interlayer insulating film 17 which covers the sidewalls of the gate electrode 16. Thus, the source regions 20 are exposed to the surface of the substrate 10 and the inner wall of the trench 19 (FIG. 4B), and come into contact with a source electrode to be formed in a subsequent step.

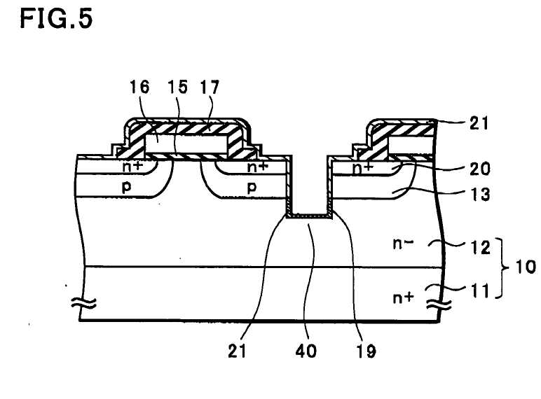

Fourth step (FIG. 5): a step of forming a first metal layer which forms a Schottky junction with at least the one conductivity type semiconductor substrate exposed to the trench below the channel layer.

A Schottky metal layer 21 such as Mo, for example, is formed on the entire surface. Here, the Schottky metal layer 21 is provided so as to cover the interlayer insulating film 17, surfaces of the source regions 20 and the inner wall of the trench 19. The Schottky metal layer 21 forms a Schottky junction with the n− type semiconductor layer 12 exposed below the channel layer 13.

Thus, a Schottky barrier diode 40 is provided in the bottom of the trench 19 by the n− type semiconductor layer 12 and the first metal layer 21 which is below the channel layer 13. Note that, in this embodiment, the Schottky metal layer 21 is formed on the entire surface. However, the Schottky metal layer 21 does not have to be provided on the entire surface as long as the Schottky metal layer 21 can be deposited, by providing a mask or the like, so as to form the Schottky junction with the n− type semiconductor layer 12 at least below the channel layer 13 on the inner wall of the trench 19. Moreover, the Schottky metal layer 21 may be not only provided on the inner wall but also buried in the trench 19.

Fifth step (see FIG. 1): a step of forming a second metal layer connected to the first metal layer, the channel layer and the source regions.

A metal layer 23 to be the source electrode is formed on the entire surface by sputtering Al containing silicon or the like. The source electrode 23 comes into contact with the entire surface of the Schottky metal layer 21, and comes into contact with the source regions 20 and the channel layer 13. Moreover, the source electrode 23 becomes the anode electrode of the Schottky barrier diode 40. Thus, the final structure shown in FIG. 1 is obtained.

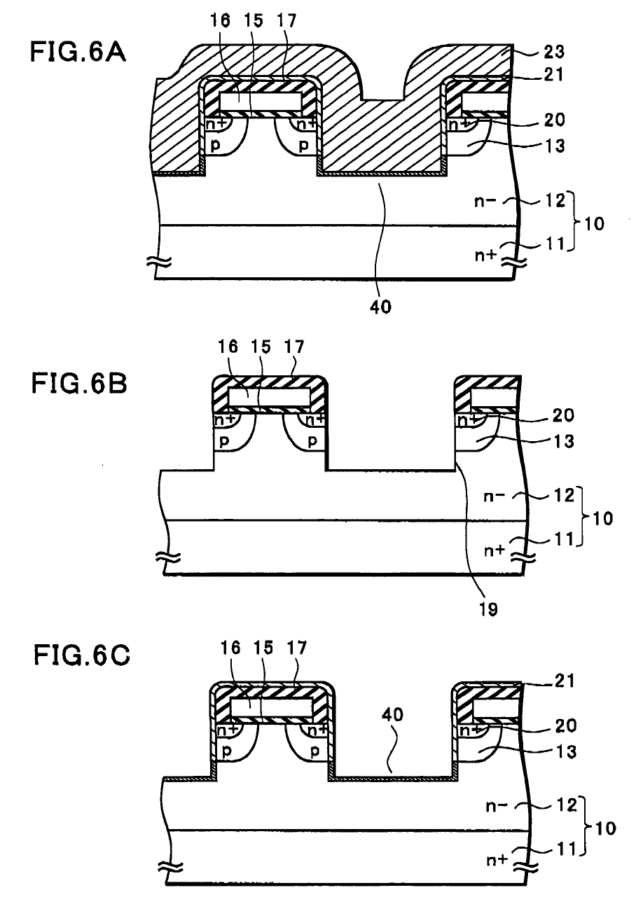

With reference to FIGS. 6A to 6C, a second embodiment will be described.

In the first embodiment, as shown in FIG. 1, the trench 19 is provided in the surface of the substrate 10 inside the interlayer insulating film 17. Meanwhile, in the second embodiment, as shown in FIG. 6A, the trench 19 is provided in such a manner that sides of a interlayer insulating film 17 and sidewalls of a trench 19 are formed in the same planes.

A source regions 20 come into contact with a source electrode 23 only on the sidewalls of the trench 19. Thus, compared to the first embodiment, a source contact resistance is somewhat increased. However, in such a case, the source regions 20 may be formed to be deep.

In the second embodiment, the trench 19 is formed, in which ends of the interlayer insulating film 17 covering the sidewalls of a gate electrode 16 and the sidewalls of the trench 19 are formed in the same planes. Accordingly, the bottom of the trench 19 is enlarged. Thus, a Schottky junction area of a Schottky barrier diode 40 is increased.

With reference to FIGS. 6B and 6C, a manufacturing method of the second embodiment will be described. Note that the method of the second embodiment is different from that of the first embodiment only in the third step. Since the other steps are the same therebetween, description will be omitted.

First, the same first and second steps as those of the first embodiment are performed.

Third step: a step of forming a trench penetrating the channel layer in the semiconductor substrate between the gate electrodes, and forming source regions.

The insulating film 17 such as a PSG film is formed on the entire surface, and the insulating film 17 is patterned by use of a resist mask having a desired pattern. Moreover, the surface of the substrate is etched. Thus, the sides and the upper surface of the gate electrode 16 are covered with the interlayer insulating film 17. At the same time, the trench 19 is formed, in which the ends of the interlayer insulating film 17 covering the sidewalls of the gate electrode 16 and the sidewalls of the trench 19 are formed in the same planes.

For example, the trench 19 has an opening of about 0.5 μm to 5 μm and a depth of about 1 μm to 10 μm. As described above, in this embodiment, a step of forming a resist mask for formation of the trench 19 is not required. Thus, a Schottky junction area is increased if a Schottky metal layer is formed in a subsequent step.

In this event, the n+ type impurity region 14 is simultaneously divided by the trench 19 to form the source regions 20. On the inner wall of the trench 19, the source regions 20 and the channel layer 13 are partially exposed. Moreover, in the bottom of the trench 19 below the channel layer 13, the n− type semiconductor layer 12 is exposed.

Thereafter, as in the case of the fourth step of the first embodiment, the Schottky metal layer 21 is formed and the Schottky barrier diode 40 is formed as shown in FIG. 6C. Furthermore, through the fifth step, the final structure shown in FIG. 6A is obtained.

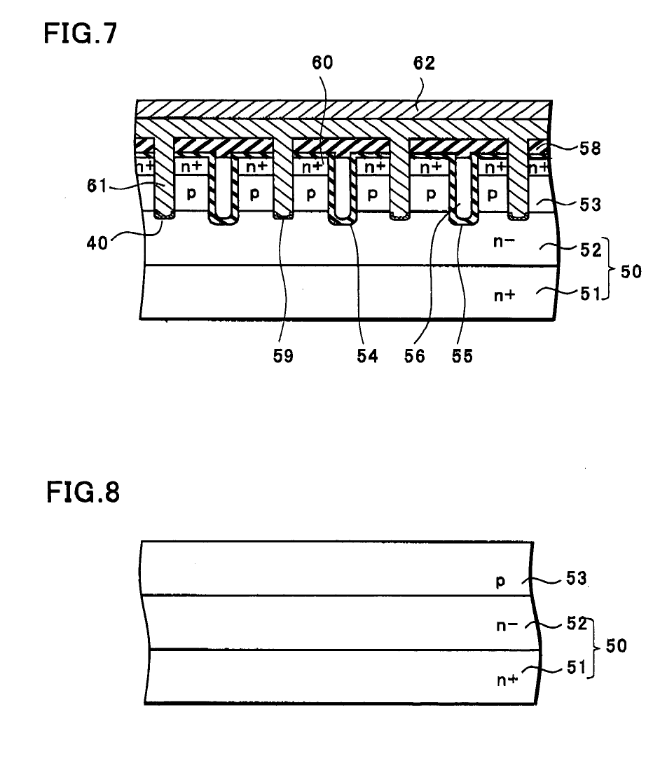

Next, with reference to FIGS. 7 to 13, a third embodiment of the present invention will be described. In the third embodiment, is applied to a MOSFET having a trench structure.

FIG. 7 shows a structure of a trench MOSFET of the third embodiment.

A substrate 50 is obtained by laminating an n− type semiconductor layer 52 on an n+ type silicon semiconductor substrate 51 by use of the epitaxial growth method or the like. The n− type semiconductor layer 52 will be a drain region of the MOSFET.

In a surface of the substrate, a channel layer 53 having p type impurities diffused therein is provided. Both of a first trench 54 and a second trench 59 are provided so as to penetrate the channel layer 53 and reach the drain region 52. The first trench 54 has its inner wall covered with a gate oxide film 55. A conductive material such as polysilicon is buried in the first trench 54 to form a gate electrode 56. Moreover, n+ type source regions 60 are provided adjacent the gate electrode 56 with the insulating film 55 interposed therebetween in the surface of the substrate 50.

The second trench 59 and the first trench 54 are alternately provided. On sidewalls of the second trench 59, the source regions 60 and the channel layer 53 are partially exposed. By providing a Schottky metal layer 61 which forms a Schottky junction (indicated by fine pattern hatching) with the n− type semiconductor layer 52 exposed to the second trench 59 at least below the channel layer 53, the Schottky barrier diode 40 is formed. The Schottky metal layer 61 is provided so as to come into contact with the source regions 60 and the channel layer 53, which are exposed to the sidewalls of the second trench 59.

A source electrode 62 is formed by providing a metal electrode layer made of Al or the like on the entire surface. The source electrode 62 is connected to the channel layer 53 and the source regions 60 through the Schottky metal layer 61.

Formation of the MOSFET having the trench structure enables a cell density to be improved and can contribute to reduction in an ON resistance.

FIGS. 8 to 13 show a method for manufacturing the MOSFET described above.

First step (FIG. 8): a step of forming an opposite conductivity type channel layer on a surface of a one conductivity type semiconductor substrate.

First, the substrate 50 is prepared, in which the drain region 52 is formed by laminating an n− type epitaxial layer on the n+ type silicon semiconductor substrate 51, and the like. After an oxide film (not shown) is formed on the surface of the substrate 50, the oxide film in a portion of the channel layer 53 to be formed is etched. By use of this oxide film as a mask, boron (B), for example, is implanted into the entire surface by a dose of 1.0×10¹³ cm⁻². Thereafter, boron is diffused to form the p type channel layer 53.

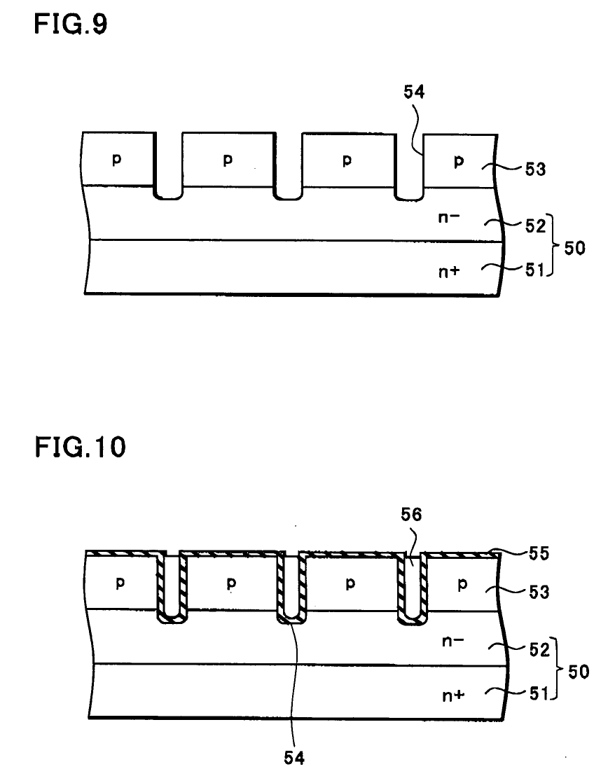

Second step (FIG. 9): a step of forming a plurality of first trenches penetrating the channel layer in the one conductivity type semiconductor substrate.

On the entire surface, a CVD oxide film (not shown) made of NSG (non-doped silicate glass) is formed by use of a CVD method. Thereafter, a mask made of a resist film is provided thereon except for a portion to be the first trenches. Subsequently, the CVD oxide film is dry-etched to be partially removed. Thus, openings in which the channel layer 53 is exposed are formed.

Furthermore, by using the CVD oxide film as a mask, the silicon semiconductor substrate in the openings is dry-etched by use of CF gas and HBr gas. Thus, the plurality of first trenches 54 are formed, which penetrate the channel layer 53 and reach the drain region 52.

Third step (FIG. 10): a step of forming an insulating film in the first trenches and forming gate electrodes.

By performing dummy oxidation, a dummy oxide film (not shown) is formed on inner walls of the first trenches 54 and the surface of the channel layer 53. Accordingly, an etching damage in dry etching is removed. This dummy oxide film formed by dummy oxidation and the CVD oxide film used as the mask are removed all together by use of an oxide film etchant such as hydrofluoric acid. Thus, a gate oxide film can be stably formed in a subsequent step. Moreover, by performing thermal oxidation at a high temperature, the openings of the first trenches 54 are made round. Thus, there is achieved an effect of avoiding field concentration in the openings of the trenches 54.

Thereafter, the gate oxide film 55 is formed. Specifically, by performing thermal oxidation, in the first trenches 54 and on the surface of the channel layer 53, the gate oxide film 55 is formed to have a thickness of, for example, about several hundred angstroms according to a threshold voltage.

Furthermore, a conductive material such as polysilicon is buried in the first trenches 54, and the gate electrodes 56 are formed. A resistance is lowered by introducing impurities into polysilicon.

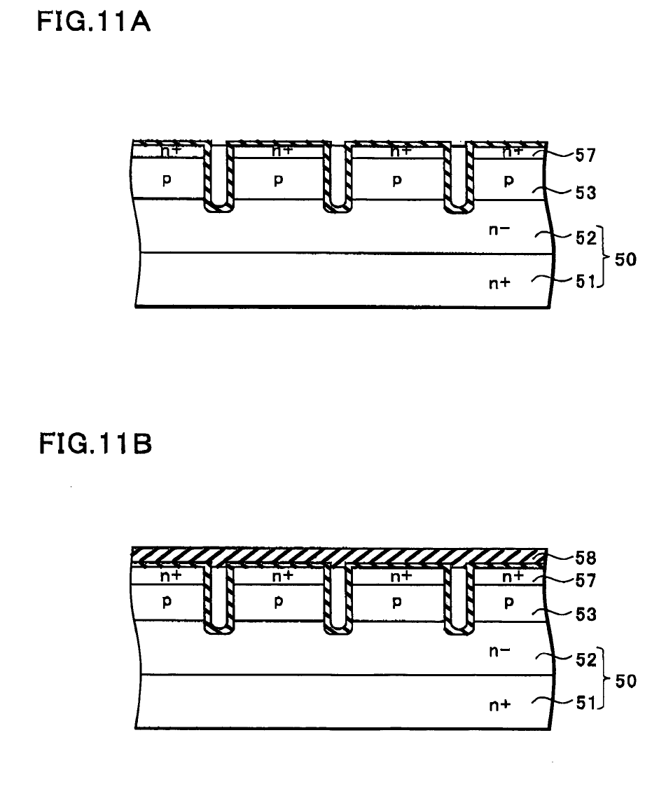

Fourth step (FIGS. 11A and 11B): a step of forming a one conductivity type impurity region on the surface of the channel layer.

After ion implantation of n type impurities such as As by a dose of about 10¹⁵ cm⁻² into the entire surface, the impurities are diffused. Thus, an n+ type impurity region 57 is formed on the surface of the channel layer 53 (FIG. 11A).

Thereafter, an insulating film 58 such as a CVD oxide film to be an interlayer insulating film is deposited thereon and reflowed. Thus, the n+ type impurity region 57 is diffused to a predetermined depth (FIG. 11B).

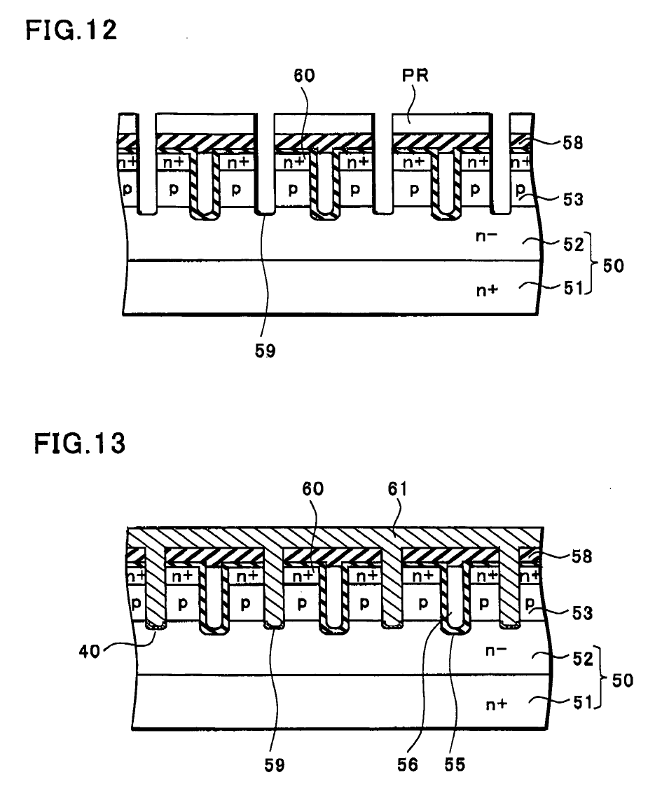

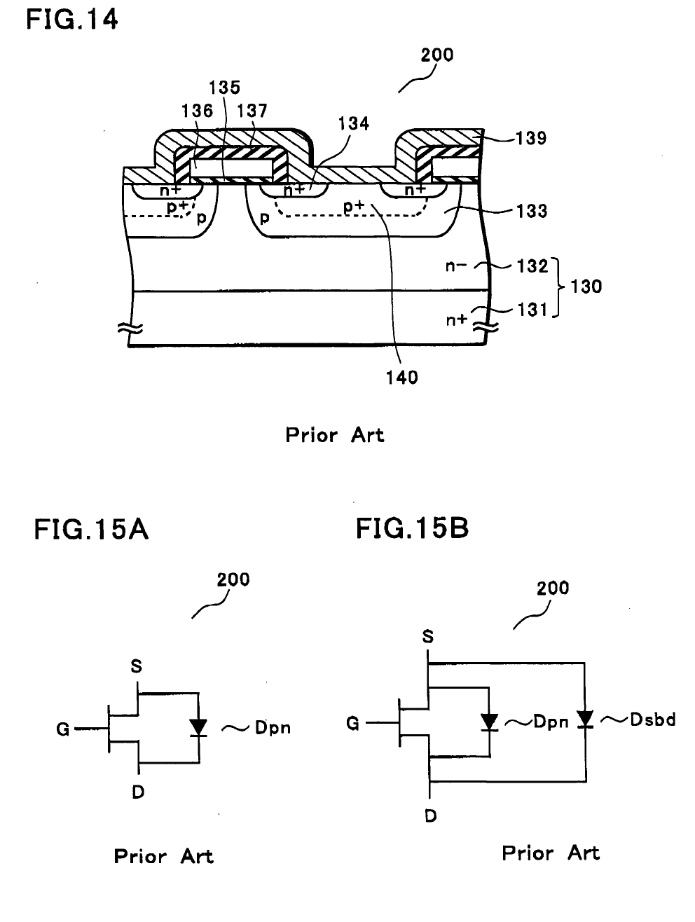

Fifth step (FIG. 12): a step of forming second trenches disposed alternately with the first trenches, and forming source regions.

A resist mask PR is provided so as to expose portions between the adjacent first trenches 54, and the insulating film 58 and the substrate 50 are etched. Thus, the second trenches 59 disposed alternately with the first trenches 54 are formed. Each of the second trenches 59 has an opening width of, for example, about 0.5 μm to 2 μm. As to a depth thereof, about 2 μm is sufficient as long as the trench penetrates the channel layer 53.

Moreover, formation of the second trenches 59 divides the n+ type impurity region 57 to form the source regions 60. On inner walls of the second trenches 59, the source regions 60 and the channel layer 53 are partially exposed.

Sixth step (FIG. 13): a step of forming a first metal layer which forms a Schottky junction with the one conductivity type semiconductor substrate exposed to the second trenches at least below the channel layer.

Subsequently, the Schottky metal layer 61 is deposited on the entire surface. The Schottky metal layer 61 forms a Schottky junction with the n− type semiconductor layer 52 exposed to the second trenches 59. Thus, a Schottky barrier diode 40 is formed.

Note that, in FIG. 13, the Schottky metal layer 61 is buried in the second trenches 59. However, if the Schottky metal layer 61 (indicated fine pattern hatching) can be selectively formed by use of a mask or the like, the Schottky metal layer 61 may be formed so as to form the Schottky junction with the n− type semiconductor layer 52 exposed to the second trenches 59 at least below the channel layer.

The source regions 60 and the channel layer 53, which are exposed to sidewalls of the second trenches 59, come into contact with the Schottky metal layer 61.

Seventh step (FIG. 7): a step of forming a second metal layer connected to the first metal layer, the channel layer and the source regions.

On the entire surface, a metal electrode layer 62 such as Al to be a source electrode is formed. The metal electrode layer 62 is connected to the source regions 60 and the channel layer 53 through the Schottky metal layer 61. The metal electrode layer becomes the source electrode 62 and also the anode electrode of the Schottky barrier diode 40.

1. A semiconductor device comprising:
a semiconductor substrate of a first general conductivity type;
a channel layer of a second general conductivity type that is formed in a surface of the semiconductor substrate;
a gate electrode disposed adjacent the channel layer;
an insulating film disposed between the gate electrode and the channel layer;
a source region of the first general conductivity type that is formed in the surface of the semiconductor substrate and disposed above the channel layer, the source region being adjacent the gate electrode and the insulating film being disposed between the gate electrode and the source region;
a trench that is adjacent the source region and penetrates the channel layer to reach part of the semiconductor substrate that is of the first general conductivity type;
a first metal layer disposed in the trench and forming a Schottky junction with said part of the semiconductor substrate; and
a second metal layer in contact with the first metal layer.

2. The semiconductor device of claim 1, wherein the first metal layer is in contact with the source region and the channel layer.

3. A semiconductor device comprising:
a semiconductor substrate of a first general conductivity type;
a channel layer of a second general conductivity type that is formed in a surface of the semiconductor substrate;
a first trench formed in the semiconductor substrate and penetrating the channel layer, an insulating film covering a sidewall of the first trench and a gate electrode filling the first trench;
a second trench formed in the semiconductor substrate and penetrating the channel layer to reach part of the semiconductor substrate that is of the first general conductivity type;
a source region of the first general conductivity type that is formed in the surface of the semiconductor substrate and disposed above the channel layer, the source region being disposed between the first and second trenches;
a first metal layer disposed in the second trench and forming a Schottky junction with said part of the semiconductor substrate; and
a second metal layer in contact with the first metal layer.

4. The semiconductor device of claim 3, wherein the first metal layer is in contact with the source region and the channel layer.

5. A method for manufacturing a semiconductor device, comprising:
forming a first gate electrode and a second gate electrode on a semiconductor substrate of a first general conductivity type;
forming a channel layer of a second general conductivity type in the semiconductor substrate;
forming between the first and second gate electrodes a trench penetrating the channel layer so as to expose part of the semiconductor substrate that is of the first general conductivity type;
forming a first metal layer so as to form a Schottky junction with the exposed part of the semiconductor substrate; and
forming a second metal layer on the first metal layer.

6. The method of claim 5, further comprising forming an impurity region of the first general conductivity type so that the forming of the trench results in forming of a source region for each of the first and second gate electrodes.

7. The method of claim 5, wherein the first metal layer is formed on an entire surface of the semiconductor substrate, and the second metal layer is formed on the entire surface of the semiconductor substrate.

8. A method for manufacturing a semiconductor device, comprising:
providing a semiconductor substrate of a first general conductivity type;
forming a channel layer of a second general conductivity type in a surface of the semiconductor substrate;
forming in the semiconductor substrate a first trench penetrating the channel layer;
forming in the first trench an insulating film to cover a sidewall of the first trench;
forming a gate electrode in the first trench;
forming in the semiconductor substrate a second trench penetrating the channel layer so as to expose part of the semiconductor substrate that is of the first general conductivity type;
forming a first metal layer so as to form a Schottky junction with the exposed part of the semiconductor substrate; and
forming a second metal layer on the first metal layer.

9. The method of claim 8, further comprising forming an impurity region of the first general conductivity type so that the forming of the second trench results in forming of a source region for the gate electrode.

10. The method of claim 8, wherein the first metal layer is formed on an entire surface of the semiconductor substrate, and the second metal layer is formed on the entire surface of the semiconductor substrate.
